(19) United States
(12) Patent Application Publication
(10) Pub. No.: US 2026/0255485 A1
(43) Pub. Date: Aug. 27, 2026

(54) PRINTED CIRCUIT BOARD

(71) Applicant: SAMSUNG ELECTRO-MECHANICS CO., LTD., Suwon-si (KR)

(72) Inventors: Ho In Jun, Suwon-si (KR); Jung Eun Lee, Suwon-si (KR); Jin Hwan Kim, Suwon-si (KR)

(73) Assignee: SAMSUNG ELECTRO-MECHANICS CO., LTD., Suwon-si (KR)

(21) Appl. No.: 19/443,657

(22) Filed: Jan. 8, 2026

(30) Foreign Application Priority Data
Feb. 24, 2025 (KR) 10-2025-0023786

(51) Int. Cl. H05K 1/11; H05K 1/02

(52) U.S. Cl. CPC H05K 1/115; H05K 1/0298; H05K 2201/09563

(57) ABSTRACT

A printed circuit board includes a plurality of insulating layers, a dielectric via disposed in at least one of the plurality of insulating layers, a first electrode layer and a second electrode layer disposed to oppose each other with the dielectric via interposed therebetween, a first through-via passing through at least one of the plurality of insulating layers, the first through-via connected to the first electrode layer, and a second through-via passing through at least one of the plurality of insulating layers, the second through-via connected to the second electrode layer.

### CROSS-REFERENCE TO RELATED APPLICATION(S)

This application claims benefit of priority to Korean Patent Application No. 10-2025-0023786 filed on February 24, 2025 in the Korean Intellectual Property Office, the disclosure of which is incorporated herein by reference in its entirety.

### TECHNICAL FIELD

The present disclosure relates to a printed circuit board.

Recently, in order to improve power characteristics of a package substrate, a structure may be adopted in which a passive component such as a chip capacitor or a silicon capacitor is mounted on the outside of a substrate, or a cavity is formed in a core of a substrate and then a passive component such as a chip capacitor or a silicon capacitor is embedded. However, in this case, a mounting process or an embedding process of the passive component may need to be additionally performed, and the cavity may need to be formed in accordance with a size of the passive component. As a result, a cavity processing space may need to be separately secured.

### SUMMARY

An aspect of the present disclosure is to provide a printed circuit board in which a cavity processing process and an embedding process are omitted by directly printing a capacitor.

However, the aspects of the present disclosure are not limited to those set forth herein, and will be more easily understood in the course of describing specific example embodiments of the present disclosure.

According to an aspect of the present disclosure, there is provided a printed circuit board including a plurality of insulating layers, a dielectric via disposed in at least one of the plurality of insulating layers, a first electrode layer and a second electrode layer disposed to oppose each other with the dielectric via interposed therebetween, a first through-via passing through at least one of the plurality of insulating layers, the first through-via connected to the first electrode layer, and a second through-via passing through at least one of the plurality of insulating layers, the second through-via connected to the second electrode layer.

According to another aspect of the present disclosure, there is provided a printed circuit board including a plurality of insulating layers having a dielectric via, a first electrode layer and a second electrode layer disposed to oppose each other with the dielectric via interposed therebetween, a first via layer passing through at least a portion of one of the plurality of insulating layers, the first via layer connected to the first electrode layer, and a second via layer passing through at least a portion of one of the plurality of insulating layers, the second via layer connected to the second electrode layer.

According to example embodiments of the present disclosure, a printed circuit board may directly print a capacitor, and thus a cavity processing process and an embedding process may be omitted.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic perspective view of an example of an electronic device;

FIG. 3 is a schematic cross-sectional view of a printed circuit board according to an example embodiment of the present disclosure;

FIGS. 4 and 5 are schematic cross-sectional views of a modification of the printed circuit board of FIG. 3;

FIG. 6 is a schematic cross-sectional view of a printed circuit board according to another example embodiment of the present disclosure;

FIGS. 7A to 7H are schematic process cross-sectional views of an example of a method of manufacturing the printed circuit board of FIG. 3; and

FIGS. 8A to 8F are schematic process cross-sectional views of an example of a method of manufacturing the printed circuit board of FIG. 6.

### DETAILED DESCRIPTION

Hereinafter, example embodiments of the present disclosure are described with reference to the accompanying drawings. The present disclosure may, however, be exemplified in many different forms and should not be construed as being limited to the specific example embodiments set forth herein. In addition, example embodiments of the present disclosure may be provided for a more complete description of the present disclosure to those skilled in the art. Accordingly, the shapes and sizes of the elements in the drawings may be exaggerated for clarity of description, and elements denoted by the same reference numerals in the drawings may be the same elements.

In order to clearly illustrate the present disclosure, portions not related to the description are omitted, and sizes and thicknesses are magnified in order to clearly represent layers and regions, and similar portions having the same functions within the same scope are denoted by similar reference numerals throughout the specification. Throughout the specification, when an element is referred to as “comprising” or “including,” it means that it may further include other elements, rather than excluding other elements, unless specifically stated otherwise.

### Electronic Device

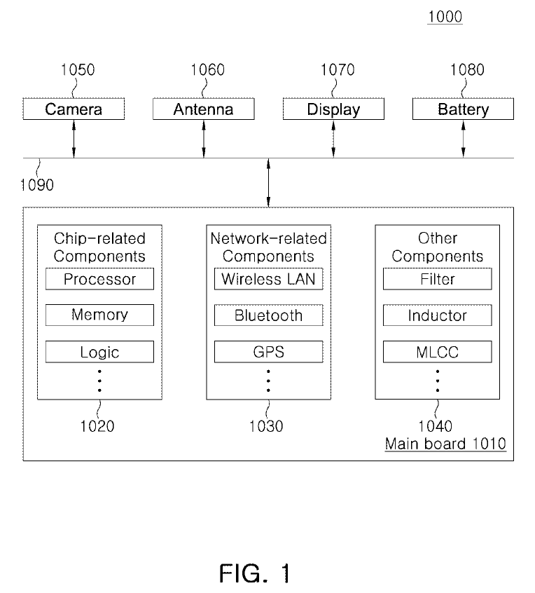

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

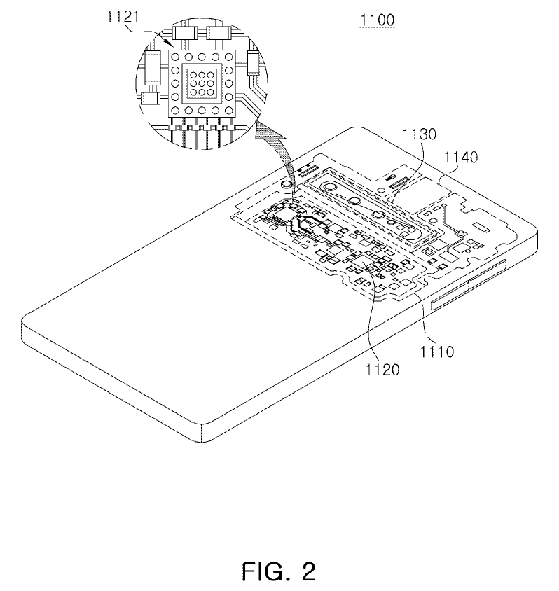

FIG. 2 is a schematic perspective view of an example of an electronic device.

Referring to the drawings, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not limited to the smartphone 1100, and may be other electronic devices, as described above.

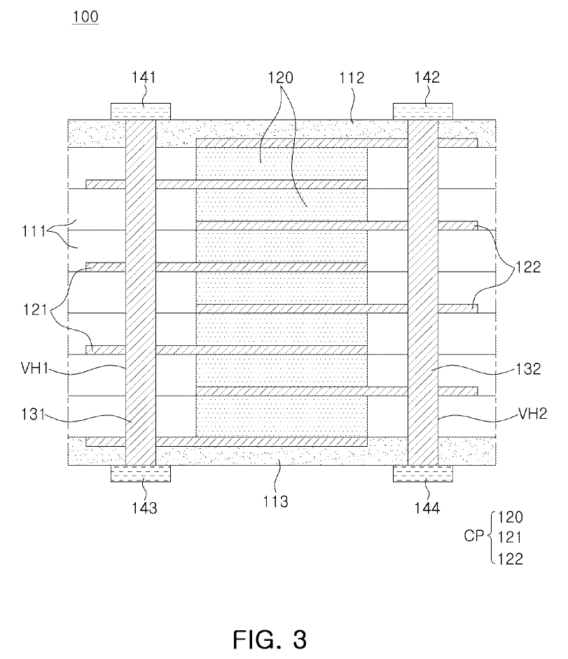

FIG. 3 is a schematic cross-sectional view of a printed circuit board according to an example embodiment of the present disclosure.

Referring to FIG. 3, a printed circuit board 100 may include a plurality of insulating layers 111, a dielectric via 120, first and second electrode layers 121 and 122, and first and second through-vias 131 and 132.

The dielectric via 120 may be disposed in at least one of the plurality of insulating layers 111. That is, the plurality of insulating layers 111 may have a dielectric via 120. For example, the dielectric via 120 may be disposed in each of the plurality of insulating layers 111. For example, the dielectric via 120 may pass through at least a portion of the insulating layer 111. In some embodiments, each of the plurality of insulating layers 111 includes the dielectric vias 120 passing through each of the plurality of insulating layers 111.

The first electrode layer 121 and the second electrode layer 122 may be disposed to oppose each other with the dielectric via 120 interposed therebetween. For example, the first and second electrode layers 121 and 122 may be alternately disposed with the dielectric via 120 interposed therebetween. The printed circuit board 100 may include a dielectric via 120 and a capacitor portion CP including the first and second electrode layers 121 and 122.

The first through-via 131 may pass through at least one of the plurality of insulating layers 111, and may be connected to the first electrode layer 121. The second through-via 132 may pass through at least one of the plurality of insulating layers 111, and may be connected to the second electrode layer 122. The first through-via 131 may pass through, for example, the plurality of insulating layers 111, and may be connected to a plurality of first electrode layers 121. The second through-via 132 may pass through, for example, the plurality of insulating layers 111, and may be connected to a plurality of second electrode layers 122. The printed circuit board 100 may include first and second via-holes VH1 and VH2 passing through the plurality of insulating layers 111, and the first and second through-vias 131 and 132 may be disposed in the first and second via-holes VH1 and VH2, respectively. The through-vias 131 and 132 may serve to electrically connect the capacitor portion CP to wiring layers 141, 142, 143, and 144, but the present disclosure is not limited thereto.

The capacitor portion CP of the printed circuit board 100 may form capacitance, and may function as an electronic device charging voltage and outputting current by using a characteristic in which charging and discharging are repeated. Accordingly, unstable power may be stabilized, and noise may be removed. In addition, the capacitor portion CP may block DC and pass AC. In addition, the capacitor portion CP may be used for stable operation of a semiconductor chip.

The printed circuit board 100 according to an example embodiment of the present disclosure may include a dielectric via 120 and electrode layers 121 and 122 formed directly on or in the insulating layer 111, and thus the capacitor portion CP having a desired size and capacitance may be easily formed in the printed circuit board 100. Accordingly, a cavity processing process and an embedding process for capacitor embedding may be omitted, and the cavity may be omitted, thereby providing a more excellent effect in terms of variation of insulating thickness.

Hereinafter, respective components included in the printed circuit board 100 will be described in more detail.

The insulating layer 111 may include an insulating material. The insulating material may include a thermosetting resin such as an epoxy resin, a thermoplastic resin such as polyimide, or a material including an inorganic filler, an organic filler, and/or a glass fiber (glass cloth, and/or glass fabric), together with the above-described resins. The insulating material may be a photosensitive material and/or a non-photosensitive material. For example, the insulating material of the insulating layer 111 may be an insulating material such as prepreg (PPG), or resin-coated copper (RCC), but the present disclosure is not limited thereto. An Ajinomoto build-up film (ABF), photoimageable dielectric (PID), bismaleimide triazine (FR-4), or bismaleimide triazine (BT) may be used as the insulating material. In addition, other polymer materials having excellent rigidity may be used as the insulating material of the insulating layer 111.

The dielectric via 120 may include a dielectric material different from that of the insulating material included in the plurality of insulating layers 111. The dielectric via 120 may be formed by filling the insulating layer 111 with a dielectric material. A dielectric constant of the dielectric material included in the dielectric via 120 may be higher than that of the insulating material included in the insulating layer 111.

The dielectric via 120 may include, for example, a mixture of dielectric particles and a resin. The dielectric via 120 may have a form in which the dielectric particles are dispersed in the resin, but the present disclosure is not limited thereto. The dielectric particles may include one or more selected from the group consisting of alumina, silica, silicon nitride, tantalum oxide, titanium oxide, calcium titanate, barium titanate, and strontium titanate particles from the viewpoint of insulation or relative dielectric constant. The resin included in the dielectric via 120 may include a material the same as the insulating material included in the insulating layer 111, or may include a material different from the insulating material included in the insulating layer 111. The resin included in the dielectric via 120 may include an organic polymer insulating material, but the present disclosure is not limited thereto.

Each of the first and second electrode layers 121 and 122 may include a metal material. The metal material, included in the first and second electrode layers 121 and 122, may include, for example, one or more selected from the group consisting of Cu, Al, Ag, Sn, Au, Ni, Pb, Ti, and alloys thereof. The first and second electrode layers 121 and 122 may include an electroless plating layer (or chemical copper) as a seed layer and an electrolytic plating layer (or electrolytic copper) as a plating layer, but the present disclosure is not limited thereto. A sputtering layer may be formed, instead of the electroless plating layer, as the seed layer. Copper foil may be further included, as necessary.

The first electrode layer 121 may include a first overlapping region overlapping the second electrode layer 122 in a lamination direction of the plurality of insulating layers 111, and a first extension region extending in a horizontal direction, perpendicular to the lamination direction, in the first overlapping region, and the second electrode layer 122 may include a second overlapping region overlapping the first electrode layer 121 in the lamination direction, and a second extending region extending in the horizontal direction in the second overlapping region.

Each of the first and second through-vias 131 and 132 may include a metal material. The metal material, included in the first and second through-vias 131 and 132, may include, for example, one or more selected from the group consisting of Cu, Al, Ag, Sn, Au, Ni, Pb, Ti, and alloys thereof. The first and second through-vias 131 and 132 may include an electroless plating layer (or chemical copper) as a seed layer and an electrolytic plating layer (or electrolytic copper) as a plating layer, but the present disclosure is not limited thereto. A sputtering layer may be included, instead of the electroless plating layer, as the seed layer, or both may be included, as necessary.

The first and second electrode layers 121 and 122 and the first and second through-vias 131 and 132 may include the same metal material. For example, each of the first and second electrode layers 121 and 122 and the first and second through-vias 131 and 132 may include Cu, but the present disclosure is not limited thereto.

The first and second through-vias 131 and 132 may include metal materials filling the first and second via-holes VH1 and VH2, respectively. That is, the first and second through-vias 131 and 132 may include filled vias filling the first and second via-holes VH1 and VH2, respectively.

The first through-via 131 may pass through the first extension region of the first electrode layer 121, and the second through-via 132 may pass through the second extension region of the second electrode layer 122.

Referring to FIG. 3, at least one of the first through-via 131 or second through-via 132 may have a pillar shape having a substantially uniform width. As will be described below, first and second through-vias 131 and 132 may be formed by filling the first and second via-holes VH1 and VH2 formed by one-time hole processing for the plurality of laminated insulating layers 111, such that at least one of the first through-vias 131 or the second through-vias 131 and 132 may have a pillar shape and a substantially uniform width.

In addition, the dielectric via 120 may have a pillar shape having a substantially constant width. Since the dielectric via 120 may be formed by filling a hole formed by one-time hole processing for the insulating layer 111, the dielectric via 120 may have a pillar shape and a substantially uniform width.

In the present disclosure, the substantially uniform width may be a concept including an approximately uniform width, and may be determined to include, for example, a process error or positional deviation occurring in a manufacturing process, an error during measurement, or the like. Here, the width may refer to a size in a horizontal direction, perpendicular to the lamination direction of the plurality of insulating layers 111.

The printed circuit board 100 may further include a first resist layer 112 disposed on an uppermost insulating layer 111, among the plurality of insulating layers 111, and a second resist layer 113 disposed on a lowermost insulating layer 111, among the plurality of insulating layers 111. The first and second resist layers 112 and 113 may include a liquid or film-type solder resist, but the present disclosure is not limited thereto, and other types of insulating materials may be used.

The printed circuit board 100 may include first wiring layers 141 and 143 disposed on the first resist layer 112 or the second resist layer 113, the first wiring layers 141 and 143 connected to the first through-via 131, and second wiring layers 142 and 144 disposed on the first resist layer 112 or the second through-via 113, the second wiring layers 142 and 144 connected to the second through-via 132. The first wiring layers 141 and 143 may be in direct contact with the first through-via 131, and the second wiring layers 142 and 144 may be in direct contact with the second through-via 132. The first wiring layers 141 and 143 may be disposed on the first resist layer 112 and the second resist layer 113, respectively, and the second wiring layers 142 and 144 may be disposed on the first resist layer 112 and the second resist layer 113, respectively.

Each of the first wiring layers 141 and 143 and the second wiring layers 142 and 144 may include a metal material. The metal material, included in the first wiring layers 141 and 143 and the second wiring layers 142 and 144, may include, for example, one or more selected from the group consisting of Cu, Al, Ag, Sn, Au, Ni, Pb, Ti, and alloys thereof. The first wiring layers 141 and 143 and the second wiring layers 142 and 144 may include an electroless plating layer (or chemical copper) as a seed layer and an electrolytic plating layer (or electrolytic copper) as a plating layer, but the present disclosure is not limited thereto. A sputtering layer may be formed as the seed layer instead of the electroless plating layer. Copper foil may be further included, as necessary.

Each of the first wiring layers 141 and 143 and the second wiring layers 142 and 144 may perform various functions according to a design thereof. For example, each of the first wiring layers 141 and 143 and the second wiring layers 142 and 144 may include a signal pattern, a power pattern, a ground pattern, or the like, and each of the patterns may have various forms such as a line (or trace), a plane (or plate), a pad (or land), and the like.

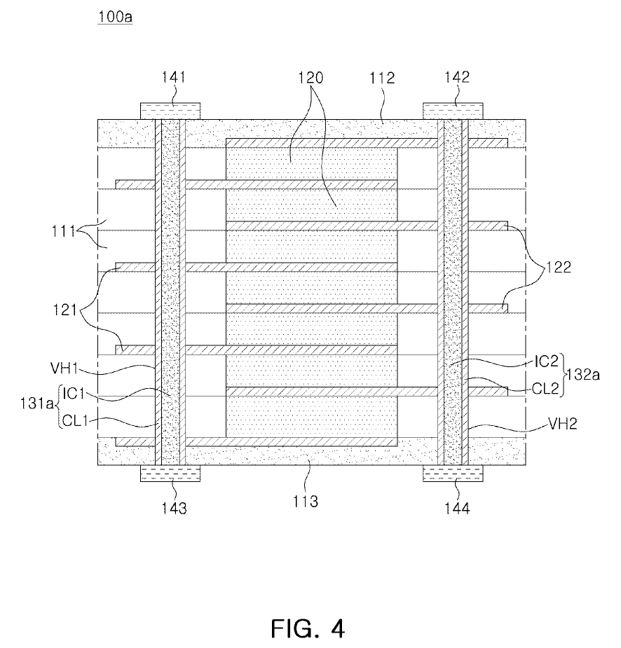

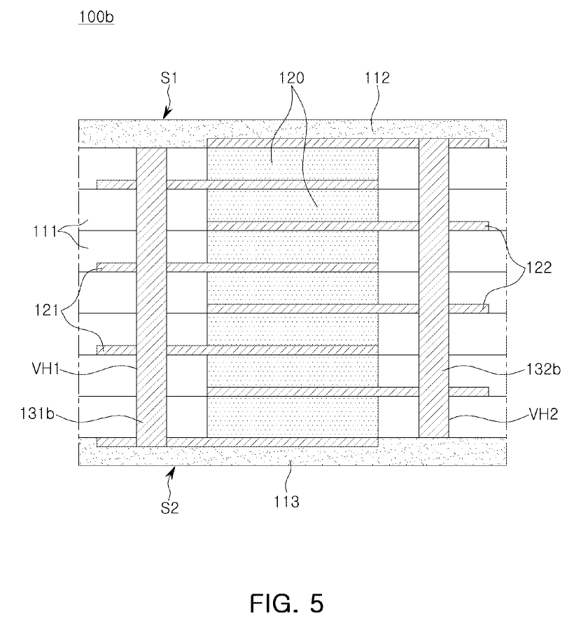

FIGS. 4 and 5 are schematic cross-sectional views of a modification of the printed circuit board of FIG. 3. Hereinafter, printed circuit boards 100a and 100b according to another example embodiment of the present disclosure will be described with reference to FIG. 4 and FIG. 5. The same/similar reference numerals are used for components, the same as/similar to those of the printed circuit board 100 described with reference to FIG. 3, and repeated descriptions will be omitted.

Referring to FIG. 4, a printed circuit board 100a may include first and second through-vias 131a and 132a. The first through-via 131a may include a first insulating core IC1 disposed in the first via-hole VH1, and a first conductive layer CL1 disposed on a side surface of the first insulating core IC1, and the second through-via 132a may include a second insulating core IC2 disposed in the second via-hole VH2, and a second conductive layer CL2 disposed on a side surface of the second insulating core IC2. That is, the first and second through-vias 131a and 132a may include conformal vias disposed along wall surfaces of the first and second via-holes VH1 and VH2, respectively. The first and second conductive layers CL1 and CL2 may include a metal material selected from the group consisting of Cu, Al, Ag, Sn, Au, Ni, Pb, Ti, and alloys thereof. The first and second insulating cores IC1 and IC2 may include an insulating material, for example, an insulating material the same as that of the insulating layer 111, but the present disclosure is not limited thereto.

Referring to FIG. 5, a printed circuit board 100b may include first and second through-vias 131b and 132b. The first through-via 131b may be disposed to be spaced apart from an upper surface S1 of the first resist layer 112 and a lower surface S2 of the second resist layer 113, and the second through-via 132b may be disposed to be spaced apart from the upper surface S1 of the first resist layer 112 and the lower surface S2 of the second resist layer 113. In this case, a mounting component and a capacitor portion installed on the printed circuit board 100b may not be directly connected to each other through the through-vias 131b and 132b, but may be connected to the mounting component through a via and/or a wiring.

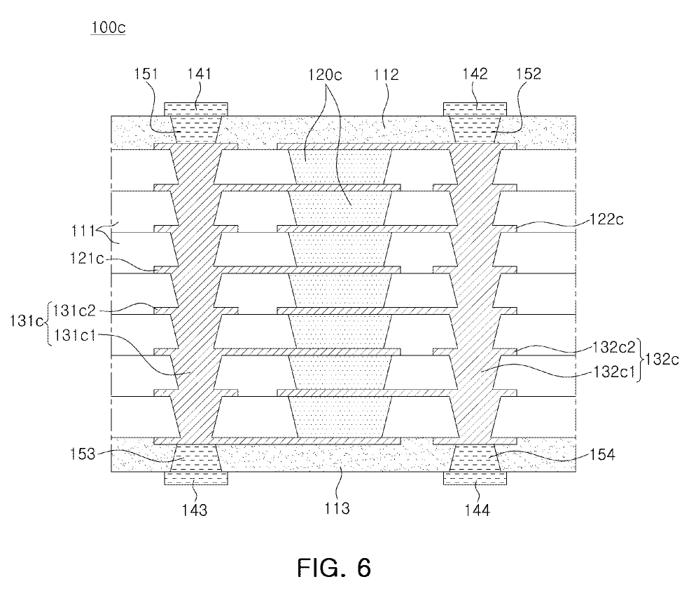

FIG. 6 is a schematic cross-sectional view of a printed circuit board 100c according to another example embodiment of the present disclosure. The printed circuit board 100c according to another example embodiment of the present disclosure will be described with reference to FIG. 6, and the same/similar reference numerals are used for components, the same as/similar to those of the printed circuit board 100 described with reference to FIG. 3, and repeated descriptions will be omitted.

The printed circuit board 100c may include a plurality of insulating layers 111, a dielectric via 120c, first and second electrode layers 121c and 122c, and first and second through-vias 131c and 132c.

Referring to FIG. 6, a width of an upper surface of the dielectric via 120c may be greater than a width of a lower surface of the dielectric via 120c. For example, a width of the dielectric via 120c may gradually decrease from the upper surface of the dielectric via 120c to the lower surface of the dielectric via 120c. For example, the dielectric via 120c may have a tapered shape having an upper end width greater than a lower end width in cross-section. As will be described below, when the insulating layer 111 is processed using a laser drilling method to fill the dielectric via 120c, a hole formed in the insulating layer 111 and the dielectric via 120c filled in the hole may have a tapered shape.

The first through-via 131c may include a plurality of first via layers 131c1 passing through at least a portion of each of the plurality of insulating layers 111. For example, the first via layer 131c1 may pass through at least a portion of one of the plurality of insulating layers 111, and may be connected to a first electrode layer 121c. The second through-via 132c may include a plurality of second via layers 132c1 passing through at least a portion of each of the plurality of insulating layers 111. The second via layer 132c1 may pass through, for example, at least a portion of one of the plurality of insulating layers 111, and may be connected to a second electrode layer 122c.

Each of the plurality of first and second via layers 131c1 and 132c1 may include a micro via. The micro via may be a filled via filling a via-hole, or a conformal via disposed along a wall surface of the via-hole. The micro via may be disposed as a stacked-type via and/or a staggered-type via. Each of the first and second via layers 131c1 and 132c1 may include a metal material. The metal material may include at least one selected from the group consisting of Cu, Al, Ag, Sn, Au, Ni, Pb, Ti, and alloys thereof.

A width of an upper surface of at least one of the plurality of first via layers 131c1 may be greater than a width of a lower surface of at least one of the plurality of first via layers 131c1. For example, a width of the first via layer 131c1 may gradually decrease from an upper surface of the first via layer 131c1 to a lower surface of the first via layer 131c1. For example, the first via layer 131c1 may have a tapered shape having an upper end width greater than a lower end width in cross-section. A width of an upper surface of at least one of the plurality of second via layers 132c1 may be greater than a width of a lower surface of at least one of the plurality of second via layers 132c1. For example, a width of the second via layer 132c1 may gradually decrease from an upper surface of the second via layer 132c1 to a lower surface of the second via layer 132c1. For example, the second via layer 132c1 may have a tapered shape having an upper end width greater than a lower end width in cross-section.

The first through-via 131c may have a form in which the first via layer 131c1 and a first metal layer 131c2 are alternately disposed in a lamination direction. The second through-via 132c may have a form in which the second via layer 132c1 and a second metal layer 132c2 are alternately disposed in the lamination direction.

The first metal layer 131c2 may be disposed at a level substantially the same as that of the second electrode layer 122c. The first metal layer 131c2 may include a metal material the same as that of the second electrode layer 122c. The second metal layer 132c2 may be disposed at a level substantially the same as that of the first electrode layer 121c. The second metal layer 132c2 may include a metal material the same as that of the first electrode layer 121c. In the present disclosure, “being disposed on substantially the same level” may include not only “being disposed in substantially the same position relative to a lamination direction and/or thickness direction” but also “being disposed in approximately the same position.”

The printed circuit board 100c may further include third via layers 151 and 153 connecting the first through-via 131c and first wiring layers 141 and 143 to each other, and fourth via layers 152 and 154 connecting the second through-via 132c and second wiring layers 142 and 144 to each other. The third via layers 151 and 153 may be disposed on first and second resist layers 112 and 113, respectively, and the fourth via layers 152 and 154 may be disposed on the first and second resist layers 112 and 113, respectively. The third and fourth via layers 153 and 154, disposed on the second resist layer 113, may be tapered in directions opposite to those of the first and second via layers 131c1 and 132c1 in cross-section, respectively, but the present disclosure is not limited thereto.

Although not illustrated, a capacitor portion of the printed circuit board 100c may be connected to a mounting component through a via and/or a wiring in addition to the third via layers 151 and 153, the fourth via layers 152 and 154, and the wiring layers 141, 142, 143, and 144.

### Method of Manufacturing Printed Circuit Board

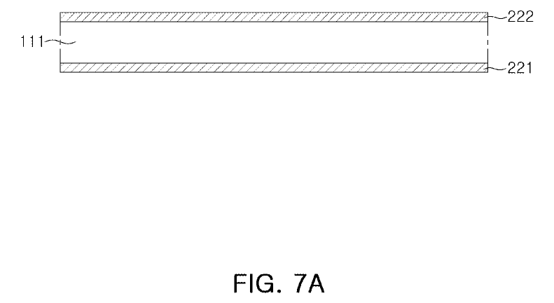

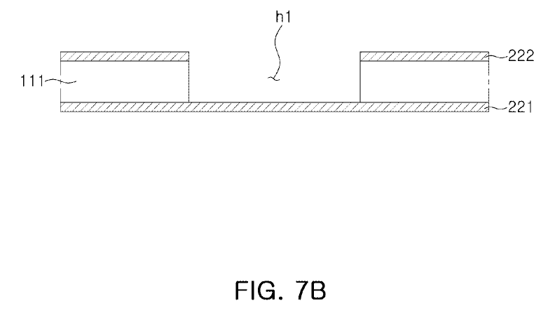

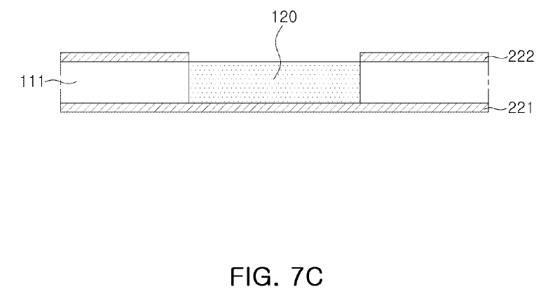

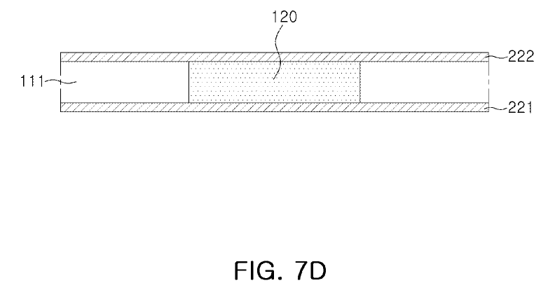

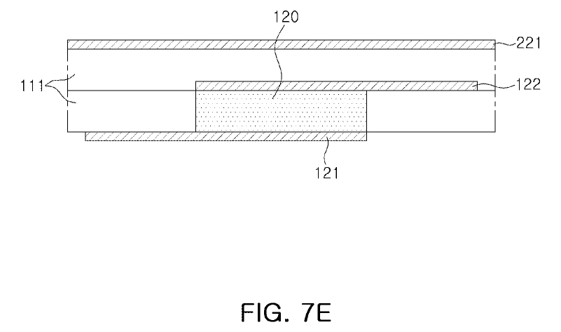

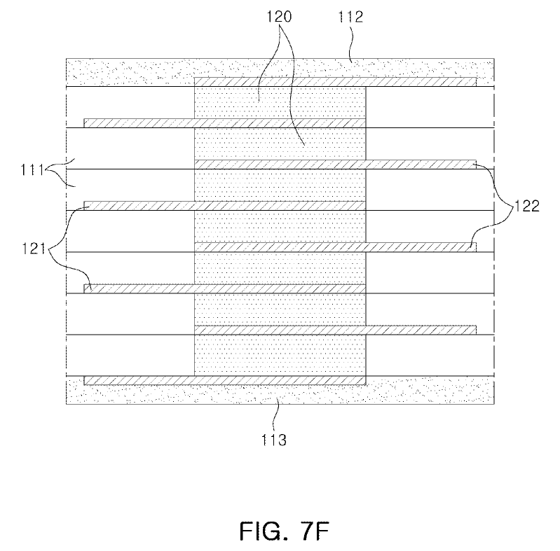

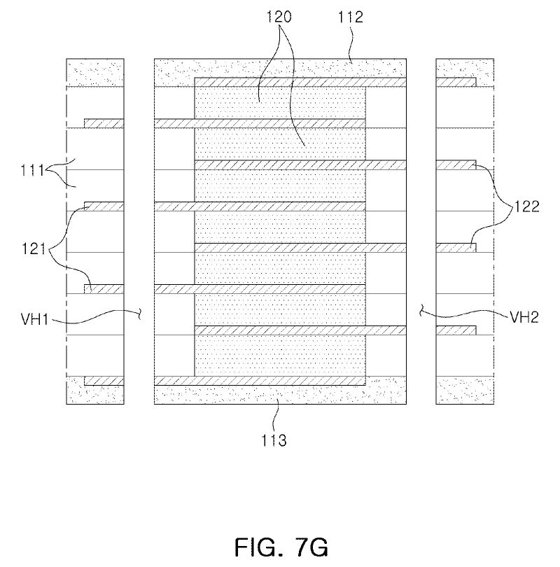

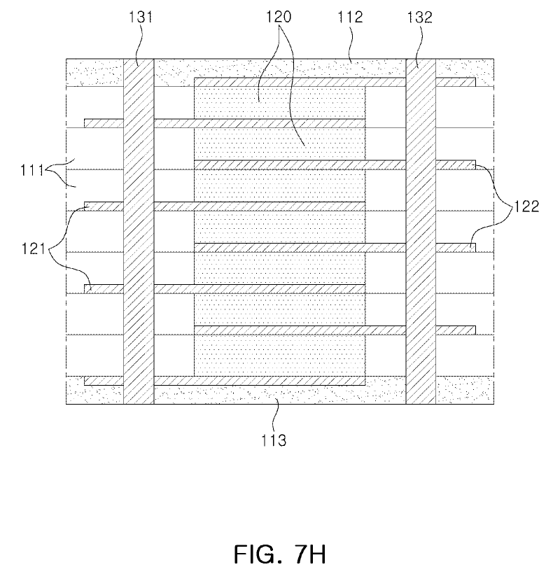

FIGS. 7A to 7H are schematic process cross-sectional views of an example of a method of manufacturing the printed circuit board of FIG. 3.

Referring to FIG. 7A, an insulating layer 111 may be prepared, and then first and second metal thin film layers 221 and 222 may be formed on upper and lower surfaces of an insulating layer 111, respectively. The metal thin film layers 221 and 222 may be formed by, for example, electroless plating, for example, chemical copper plating. The metal thin film layers 221 and 222 may be formed using a sputtering method, as necessary.

Referring to FIG. 7B, a hole h1 may be formed in the insulating layer 111 having the upper and lower surfaces on which the metal thin film layers 221 and 222 are formed. The hole h1 may be formed, for example, using a method such as mechanical processing or the like.

Referring to FIG. 7C, a dielectric via 120 may be formed by filling the hole h1 with a dielectric material. The dielectric material may be, for example, a mixture of dielectric particles and a resin. Referring to FIG. 7D, an empty space formed on the upper surface of the dielectric via 120 may be filled with a metal material using electroless plating (chemical copper), electrolytic plating (electrolytic copper), and/or a sputtering method. Accordingly, the second metal thin film layer 222 may cover the upper surface of the insulating layer 111.

Referring to FIG. 7E, a circuit may be formed by performing an etching process on the first and second metal thin layers 221 and 222 to remove portions of the first and second metal thin layers 221 and 222. Accordingly, the first and second electrode layers 121 and 122 may be formed. Subsequently, the insulating layer 111 may be laminated, and a first metal thin film layer 221 may be formed on the insulating layer 111.

Referring to FIG. 7F, after the processes illustrated in FIGS. 7A to 7E are repeated, first and second resist layers 112 and 113 may be formed on an uppermost insulating layer 111 and a lowermost insulating layer 111, respectively.

Referring to FIG. 7G, first and second via-holes VH1 and VH2 may be formed to pass through a plurality of insulating layers 111 and the first and second resist layers 112 and 113. The first and second via-holes VH1 and VH2 may be formed using a method such as mechanical processing or the like.

Referring to FIG. 7H, the first and second through-vias 131 and 132 may be formed by filling a metal material in the first and second via-holes VH1 and VH2. The first and second through-vias 131 and 132 may be formed using electroless plating (chemical copper), electrolytic plating (electrolytic copper), and/or a sputtering method.

Finally, the printed circuit board 100 of FIG. 3 may be manufactured by forming wiring layers 141, 142, 143, and 144 on the first and second resist layers 112 and 113 using electroless plating, electrolytic plating (electrolytic copper), and/or a sputtering method.

The first and second via-holes VH1 and VH2 may not be entirely filled with a metal material, but conductive layers CL1 and CL2, disposed along wall surfaces of the first and second via-holes VH1 and VH2, may be formed using electroless plating (chemical copper) or the like, and a remaining region may be filled with an insulating material to manufacture the printed circuit board 100a including the through-vias 131a and 132a of FIG. 4.

In addition, before the first and second resist layers 112 and 113 are formed in FIG. 7F, the printed circuit board 100b of FIG. 5 may be manufactured by forming the first and second via-holes VH1 and VH2, and forming the first and second through-vias 131b and 132b in the first and second via-holes VH1 and VH2, respectively.

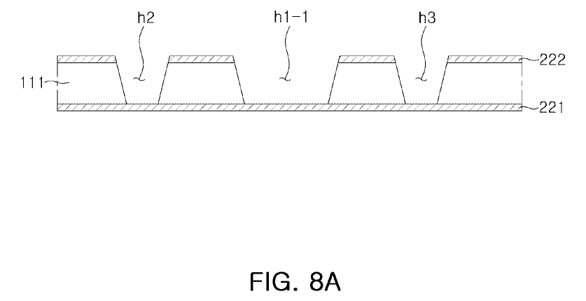

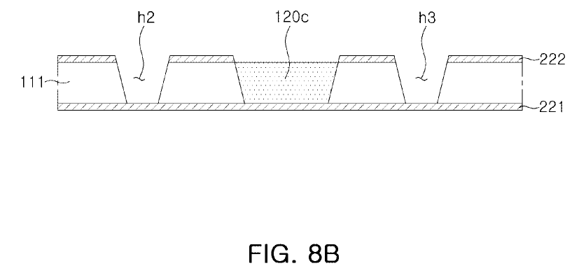

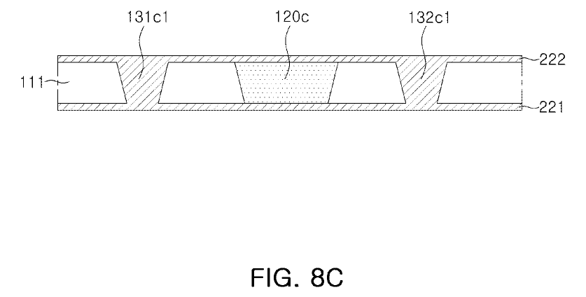

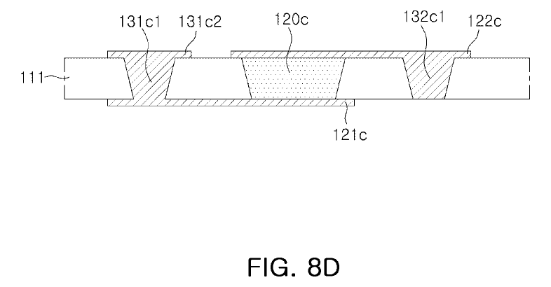

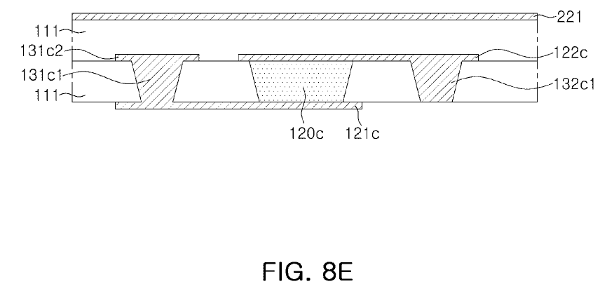

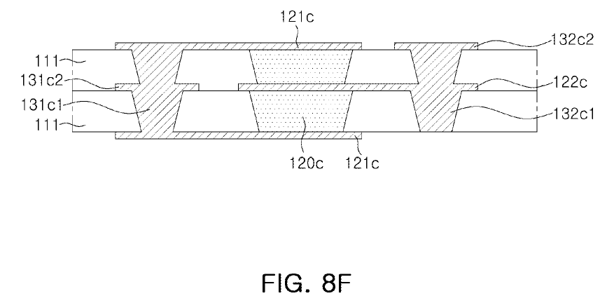

FIGS. 8A to 8F are schematic process cross-sectional views of an example of a method of manufacturing the printed circuit board 100c of FIG. 6.

First, an insulating layer 111 on which the first and second metal thin film layers 221 and 222 illustrated in FIG. 7A are formed may be prepared.

Referring to FIG. 8A, holes h1-1, h2, and h3 may be formed in the insulating layer 111. The holes h1-1, h2, and h3 may be formed using a laser drilling method or the like. Accordingly, the holes h1-1, h2, and h3 may have a tapered shape having an upper end width greater than a lower end width in cross-section.

Referring to FIG. 8B, a dielectric via 120c may be formed by filling the hole h1-1 with a dielectric material. Referring to FIG. 8C, the holes h2 and h3 may be filled with a metal material using electroless plating (chemical copper), electrolytic plating (electrolytic copper), and/or a sputtering method to form the first and second via layers 131c1 and 132c1. In addition, empty spaces formed on upper surfaces of the first and second via layers 131c1 and 132c1 and the dielectric via 120 may be filled with a metal material, such that a second metal thin film layer 222 may cover an upper surface of the insulating layer 111

Referring to FIG. 8D, an etching process may be performed on the first and second metal thin film layers 221 and 222 to partially remove the first and second metal thin film layers 221 and 222, thereby forming a circuit. Accordingly, first and second electrode layers 121c and 122c and a first metal layer 131c2 may be formed.

Referring to FIG. 8E, an additional insulating layer 111 may be laminated, and a first metal thin film layer 221 may be formed on the insulating layer 111. Referring to FIG. 8F, an etching process may be performed on the first metal thin film layer 221 to remove a portion of the first metal thin film layer 221. Accordingly, the first electrode layer 121c and the second metal layer 132c2 may be formed.

After the processes illustrated in FIG. 8A to FIG. 8F are repeated, first and second resist layers 112 and 113 may be formed on an uppermost insulating layer 111 and a lowermost insulating layer 111, respectively. Finally, after hole processing is performed on the resist layers 112 and 113, third via layers 151 and 153, fourth via layers 152 and 154, and wiring layers 141, 142, 143, and 144 may be formed to manufacture the printed circuit board 100c of FIG. 6.

While example embodiments have been shown and described above, it will be apparent to those skilled in the art that modifications and variations could be made without departing from the scope of the present disclosure as defined by the appended claims.

In addition, the term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

As used herein, the term “connected” may not only refer to “directly connected” but also “indirectly connected” by means of an adhesive layer or the like. The term “electrically connected” may include both a case in which elements are “physically connected” and a case in which elements are “not physically connected.” In addition, the terms “first,” “second,” and the like may be used to distinguish an element from another element, and may not imply any particular order and/or importance, or others in relation to the elements. In some cases, a first element may be referred to as a second element, and similarly, a second element may be referred to as a first element without departing from the scope of the example embodiments.

What is claimed is:

1. A printed circuit board comprising: a plurality of insulating layers; a dielectric via disposed in at least one of the plurality of insulating layers; a first electrode layer and a second electrode layer disposed to oppose each other with the dielectric via interposed therebetween; a first through-via passing through at least one of the plurality of insulating layers, the first through-via connected to the first electrode layer; and a second through-via passing through at least one of the plurality of insulating layers, the second through-via connected to the second electrode layer.

2. The printed circuit board of claim 1, wherein the dielectric via includes a dielectric material different from an insulating material included in the plurality of insulating layers.

3. The printed circuit board of claim 1, wherein the dielectric via includes a mixture of dielectric particles and a resin.

4. The printed circuit board of claim 1, wherein each of the plurality of insulating layers includes the dielectric via passing through each of the plurality of insulating layers.

5. The printed circuit board of claim 1, wherein at least one of the first through-via or the second through-via has a pillar shape having a substantially uniform width.

6. The printed circuit board of claim 1, wherein the dielectric via has a pillar shape having a substantially uniform width.

7. The printed circuit board of claim 1, further including first and second via-holes passing through the plurality of insulating layers,
wherein the first and second through-vias include a metal material filling the first and second via-holes, respectively.

8. The printed circuit board of claim 1, further including first and second via-holes passing through the plurality of insulating layers, wherein the first through-via includes a first insulating core in the first via-hole, and a first conductive layer disposed on one or both side surfaces of the first insulating core, and the second through-via includes a second insulating core in the second via-hole, and a second conductive layer disposed on one or both side surfaces of the second insulating core.

9. The printed circuit board of claim 1, further comprising: a first resist layer disposed on an uppermost insulating layer, among the plurality of insulating layers; a second resist layer disposed on a lowermost insulating layer, among the plurality of insulating layers; a first wiring layer disposed on the first or second resist layer, the first wiring layer connected to the first through-via; and a second wiring layer disposed on the first or second resist layer, the second wiring layer connected to the second through-via.

10. The printed circuit board of claim 1, further comprising: a first resist layer disposed on an uppermost insulating layer, among the plurality of insulating layers; and a second resist layer disposed on a lowermost insulating layer, among the plurality of insulating layers, wherein the first and second through-vias are disposed to be spaced apart from an upper surface of the first resist layer and a lower surface of the second resist layer, respectively.

11. The printed circuit board of claim 1, wherein a width of an upper surface of the dielectric via is greater than a width of a lower surface of the dielectric via.

12. The printed circuit board of claim 1, wherein the first through-via includes a plurality of first via layers passing through at least a portion of each of the plurality of insulating layers, the second through-via includes a plurality of second via layers passing through at least a portion of each of the plurality of insulating layers, a width of an upper surface of at least one of the plurality of first via layers is greater than a width of a lower surface of at least one of the plurality of first via layers, and a width of an upper surface of at least one of the plurality of second via layers is greater than a width of a lower surface of at least one of the plurality of second via layers.

13. A printed circuit board comprising: a plurality of insulating layers having a dielectric via; a first electrode layer and a second electrode layer disposed to oppose each other with the dielectric via interposed therebetween; a first via layer passing through at least a portion of one of the plurality of insulating layers, the first via layer connected to the first electrode layer; and a second via layer passing through at least a portion of one of the plurality of insulating layers, the second via layer connected to the second electrode layer.

14. The printed circuit board of claim 13, wherein the dielectric via includes a mixture of dielectric particles and a resin.

15. The printed circuit board of claim 13, wherein the dielectric via has a tapered shape having an upper end width greater than a lower end width in cross-section.

16. The printed circuit board of claim 13, wherein the first and second via layers have a tapered shape having an upper end width greater than a lower end width in a cross-section, respectively.
